(19) United States
(12) Patent Application Publication
(10) Pub. No.: US 2024/0400375 A1
(43) Pub. Date: Dec. 5, 2024

(54) STRAIN SENSOR SWITCH FOR TIMING BASED SENSING

(71) Applicant: Carnegie Mellon University, Pittsburgh, PA (US)

(72) Inventors: Regan Kubicek, Pittsburgh, PA (US); Sarah Bergbreiter, Pittsburgh, PA (US); Mahnoush Babaei, Pittsburgh, PA (US); Alison I. Weber, Pittsburgh, PA (US); Sukjun Kim, PIttsburgh, PA (US); Tom Daniel, Pittsburgh, PA (US)

(73) Assignee: Carnegie Mellon University, Pittsburgh, PA (US)

(21) Appl. No.: 18/735,123

(22) Filed: Jun. 5, 2024

Related U.S. Application Data
(60) Provisional application No. 63/471,027, filed on Jun. 5, 2023.

(51) Int. Cl. B81B 3/00; B81C 1/00; G01L 1/22

(52) U.S. Cl. CPC B81B 3/0021; B81C 1/00373; G01L 1/2287; B81B 2201/018; B81B 2201/0292; B81B 2203/0109; B81B 2203/06; B81C 2201/0121; B81C 2201/0143

(57) ABSTRACT

A strain sensor utilizes an ohmic-based contact switch to detect strain. The sensor can be incorporated into other structures, such as an artificial flapping wing, to detect strain and other parameters, including air flow disturbances. The sensors are fabricated using an additive manufacturing process, with a layer of gold or other conductive material applied for electrical conductivity and UV laser ablation for electrical isolation. The sensor design incorporates mechanical amplification, converting small strains into larger displacements that close contact pads, resulting in an ohmic switch activated at a specific strain threshold. Unlike traditional sensors, the switch provides a high or low state output directly without the need for additional amplification or post-processing. The device can detect disturbances in flapping wing cycles and obtain yaw rotation information, with potential applications in other aircraft for disturbance detection.

### CROSS-REFERENCE TO RELATED APPLICATIONS

This application claims the benefit under 35 U.S.C. § 119 of U.S. Provisional Application Ser. No. 63/471,027, filed on Jun. 5, 2023, which is incorporated herein by reference.

### STATEMENT REGARDING FEDERALLY SPONSORED RESEARCH

This invention was made with United States government support under FA9550-19-1-0386 and FA9550-14-1-0398 awarded by the Air Force Office of Scientific Research (AFSOR). The U.S. government has certain rights in the invention.

### BACKGROUND OF THE INVENTION

The present disclosure generally relates to strain sensors. More specifically, the disclosure relates to a 3D printed micro-electromechanical system (MEMS) switch-based sensor array that can be printed on flexible substates.

Fabricating MEMS devices on flexible substrates enables compliant, lightweight device integration essential in several applications, such as flexible displays or robotics. For example, sensing ‘skins’ composed of MEMS sensor arrays on flexible substrates can be used on humanoid robotics. However, creating flexible sensor arrays similar to those found in biological systems like our own skin involves numerous engineering challenges. While larger (>1 cm) flexible sensor arrays have become more common, microscale MEMS sensors are typically limited to rigid silicon wafers to take advantage of standard microfabrication processes. In addition, traditional MEMS sensor arrays typically require significant design and fabrication time ranging from days to months.

Some of these challenges have previously been tackled using transfer printing—an approach designed to transfer MEMS devices fabricated on a rigid donor substrate to a flexible receiver substrate through bonding. While this solves the problem of putting MEMS on a flexible substrate, transfer printing still has fabrication limitations, misalignment challenges, and requires significant cleanroom time to fabricate the MEMS devices. To reduce fabrication time, rapid prototyping through 3D printing could be used. However, prior attempts have been limited to rigid substrates. Therefore, it would be advantageous to develop a micro-electromechanical system that can be implemented on a flexible substrate.

### BRIEF SUMMARY

According to embodiments of the present disclosure is a micro-electromechanical system that can be used as a strain sensor in various applications. Methods to rapidly fabricate MEMS sensor arrays on a highly flexible substrate are also disclosed. The fabrication methods take advantage of rapid prototyping by using the two-photon polymerization process and extend its utility through the design of new processes to print complex structures (including long overhangs without supports) directly onto 50 μm thin PET sheets. Sputtered metal is used to provide electrical conductivity to the sensors. Laser ablation of deposited metal is used to achieve electrical isolation. This rapid prototyping process enables MEMS devices to be directly printed on flexible substrates, drastically decreasing fabrication time, and reducing cost, while also presenting 3D devices that are not achievable or challenging to achieve with traditional 2D processes.

The fabrication process can be used to create a strain sensor inspired by mechano-sensors found in the wings of certain moths. The fabricated sensors enable both higher density arrays as well as greater substrate compliance compared to those found in nature. The result is a strain sensor that activates at a particular strain threshold, acting as a switch. When combined with a simple voltage divider, the contact switch provides a sufficient change in voltage to be captured by a digital input on a microcontroller.

The sensor is a digital, bio-inspired strain sensor. These temporal sensors can be used to infer the magnitude of disturbances on a winged vehicle without directly encoding strain itself, but instead by encoding the timing at which a particular strain value is reached. When the wings with printed sensors are flapped and subjected to wind gusts, the signal generated by the sensors can easily distinguish the onset of a wind gust within a wingbeat by analyzing changes in the digital signal.

### BRIEF DESCRIPTION OF THE SEVERAL VIEWS OF THE DRAWINGS

FIG. 1 is a sensor array on a flexible substrate.

FIG. 2 is a diagram showing the fabrication process, according to one embodiment.

FIG. 3 is an example of a flexible wing containing several strain sensors.

FIG. 4 is an image of a sensor, according to one embodiment.

FIG. 5 is a diagram showing the fabrication process, according to an alternative embodiment.

FIG. 6 illustrates activation of a strain switch.

FIG. 7 illustrates aspects of bending strain testing.

FIG. 8 shows a strain sensor incorporated onto a flexible wing.

FIG. 9 is a schematic of a sensor.

FIG. 10 depicts a circuit diagram and sensor outputs.

FIG. 11 depicts timing differences in digital signals obtained from three sensors with different strain thresholds.

FIG. 12 shows wind disturbance data.

### DETAILED DESCRIPTION

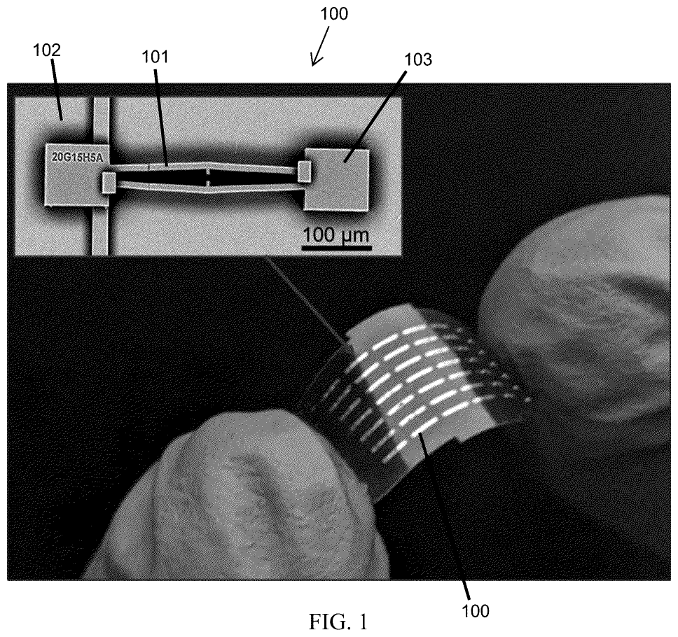

According to embodiments of the disclosure is strain sensor 100, as shown in FIG. 1. The sensor 100 comprises beams 101 suspended off a flexible substrate 102, In one embodiment, the flexible substrate 102 is fabricated from polyethylene terephthalate (PET); however, other polymers, composites, or other flexible materials can be used. The beams 101 are configured to add mechanical amplification, turning a small displacement due to strain in the substrate 102 or an object to which the sensor 100 is mounted into a large displacement. The large displacement closes contact pads 110 along the beams 101, creating an ohmic switch 111 activated at a certain strain threshold. The contact pads 110 can be made from gold, palladium, gold alloys, alloys containing silver, platinum, or palladium, or other similar conductive materials. In one example embodiment, gold is used due to its resistance to oxidation, enabling ohmic contact. FIG. 1 shows an array of sensors 100 mounted on a flexible substrate 102, with the inset of FIG. 1 showing a single sensor 100.

This switch 111 is incorporated with a voltage divider that provides a high state when the switch 111 is closed and a low state when the switch 111 is open. Thus, the switch 111 has an on/off state capable of providing a digital output. Traditional sensors obtain an analog signal which is amplified with additional hardware. The noisy amplified signal must be post-processed to obtain a usable signal. Here, the strain sensor 100 differs from traditional sensors by providing an improved signal-to-noise ratio. Further, the strain sensor 100 provides an output that can be directly digitally sampled and thus is not limited by analog-to-digital conversion, but instead by the clocking speed of a processor.

A variety of fabrication techniques employed in the field of MEMS sensors can be utilized. Two such non-limiting examples are highlighted below.

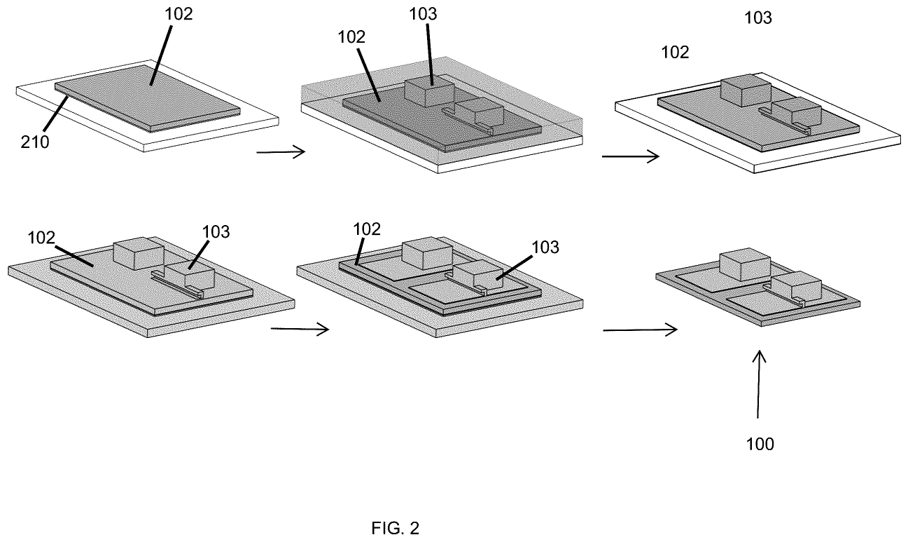

The first fabrication process, shown in FIG. 2, combines two-photon polymerization, metal sputtering, and laser ablation to facilitate rapid prototyping of 3D MEMS on flexible substrates 102 to create the sensor 100. Structures 103 are directly printed on PET as the substrate 102 using two-photon polymerization with a Nanoscribe Photonic Professional GT+ device (Nanoscribe Gmbh). The structures 103 include the printed components of the sensor 100, other structures that aid in the metal deposition process, and may include the beams 101. In the first step of the fabrication process, an Indium/Tin oxide-coated PET sheet 102 is cut to shape using an LPKF U4 laser. During this process, fiducials are added for alignment during printing and for final laser ablation. The substrate 102 used in the fabrication process is an off-the-shelf 300 Ω/sq, 50 μm sheet. The Indium/Tin oxide coating is not used for its conductivity but instead provides a refractive index contrast to the adhesive layer 210, which is often required for interface finding in two-photon polymerization.

One challenge in handling flexible substrates using existing tools is keeping the substrate flat during processing. To maintain flatness, in one example embodiment, Crystalbond 555 is used as an adhesion layer 210 to bond the substrate 102 flat during the fabrication process. In this example embodiment, a 25 mm×25 mm×0.7 mm silica glass slide is cleaned with isopropyl alcohol and placed on a hotplate at 70° C. Crystalbond 555 is applied to the glass slide, and the PET substrate 102 is placed coated side down, allowing the capillary forces to pull it uniformly on the glass. The prepared slide is then placed in a vacuum oven at 85° C. with a gauge pressure of 25 inHg for 30 minutes to remove air bubbles trapped under the PET substrate 102. Trapped bubbles can cause interface finding issues during printing and deformations in the substrate 102 while under a high vacuum during subsequent sputtering. In other embodiments, other forms of adhesion layers 210 can be used, along with ranges of physical dimensions, time temperature, and pressures.

After removing bubbles, the slide-mounted substrate 102 is placed back on a hotplate at 60° C. and covered. The hotplate is turned off and left to cool for 20 minutes to room temperature. This slow cooling prevents artifacts from forming in the adhesion layer 210, leaving an optically clear layer under the substrate 102 that is ideal for interface finding during the 3D printing process. Automatically finding an interface is a step in printing using two-photon polymerization that improves the outcome. A weak interface signal can result in structures printed too deep or above the substrate 102. When printing larger structures with multiple split blocks, an insufficient interface or artifact can lead to misalignment between blocks.

By removing bubbles and slowly cooling the adhesion layer 210, the resulting ITO/adhesion layer interface provides a robust and consistent interface signal across the entire substrate 102 allowing for larger arrays to be printed. It should also be noted that the ITO/adhesion layer interface is on the bottom of the substrate 102, and structures 103 are printed on the top. As a result, the z-offset must be adjusted to account for the substrate 102 thickness. This offset can be found by printing test structures and increasing the z-offset until the structures 103 are visible on the top of the substrate 102. A z-offset of 52 μm was added in this example embodiment to print structures 103 on the non-coated side of the substrate 102. In alternative embodiments, other types of adhesion layers 102 can be used, along with ranges of physical dimensions, time temperature and pressures.

During fabrication, once the substrate 102 is prepared, a Nanoscribe Dip-in Laser Lithography (DiLL) process is used to print 3D structures on the substrate 102. IP-S resist is drop cast onto the substrate 102, as shown in FIG. 2, and the structures 103 were printed with the 25× objective and a laser power of 50 mW. The laser power used for the base layer is dropped to 35 mW to alleviate bubbling at the IP-S/substrate interface.

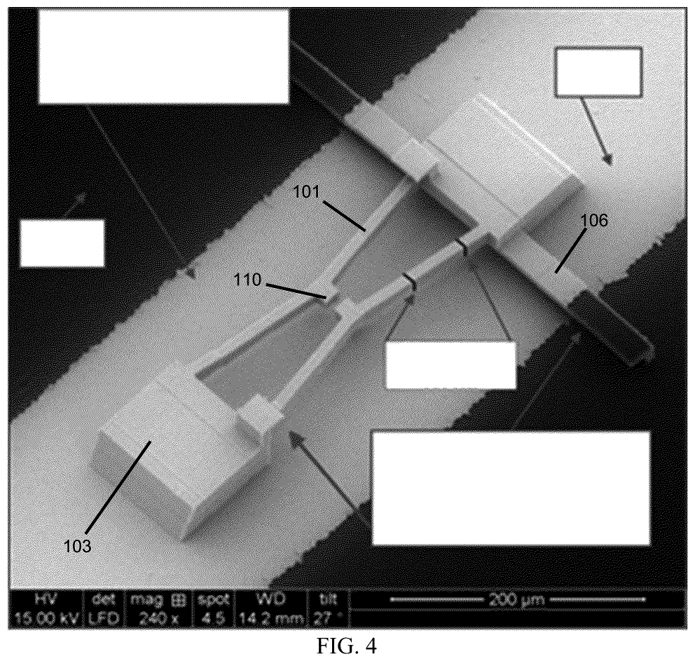

Another challenge addressed in this fabrication process is printing long (e.g., >1 mm) overhanging structures 106. Printing with IP-S resist traditionally requires support structures to prevent drift and misalignment during printing. To print large structures in general, the Nanoscribe needs to break printing steps into blocks—the 25× objective used in this process can print up to a 280×280 μm square area at one time before the stage moves to print the next square. These areas are called ‘split blocks’. Long overhanging structures 106 can be fabricated by reducing the split block size to 50 μm, which prevents drift in IP-S during printing. The overhanging structures 106 are visible in FIG. 4, which is a scanning electron microscope image of a sensor 100 having local and global electrical isolation as well as long unsupported structures. After printing, the structures 103 were developed in Propylene glycol methyl ether acetate (PGMEA) for 20 min and rinsed in isopropyl alcohol. In other embodiments, comparable process steps and tools can be used, as well as variations in ranges of dimensions, power, and time.

To provide electrical conductivity to the 3D polymer structures 103, gold is then sputtered to a thickness of 150 nm using a Perkin Elmer 6J Sputtering System. As discussed above, other suitable metals also can be used. Several approaches can be used to pattern the gold and provide electrical isolation. Electrical isolation permits proper functioning of the device 100. For example, for a strain sensor 100, electrical isolation allows the circuit formed by the sensor 100 to act as a switch, where the circuit is normally open, until a strain causes the beams 101 to deflect and contact each other, closing the circuit. In one approach, the overhanging structures 106 can be added in the 3D design and provide self-shadowing to prevent metal from being deposited underneath during sputtering. In the second approach, an LPKF ProtoLaser U4 can be used to selectively remove (i.e. ablate) the deposited gold from both the substrate 102 and printed structures 103. The sample was aligned using the established fiducials, and gold was removed using a laser power of 0.6 W, resulting in electrical isolation across the substrate 102. In other embodiments, comparable process steps and tools can be used, as well as variations in dimensions and power (as well as other operating parameters).

After laser ablation, the sensor 100 is placed on a hotplate at 70° C. to release the PET substrate 102 from the glass slide. The sensor 100 is rinsed in a bath of deionized water to remove excess adhesion layer 210 and then isopropyl alcohol is used as a final cleaning step. The example sensor 100 in FIG. 1 is a 42-sensor array printed using this process. The entire process from sensor design to testing can be accomplished in a single day. Again, in other embodiments, comparable process steps and tools can be used, as well as variations in operating parameters.

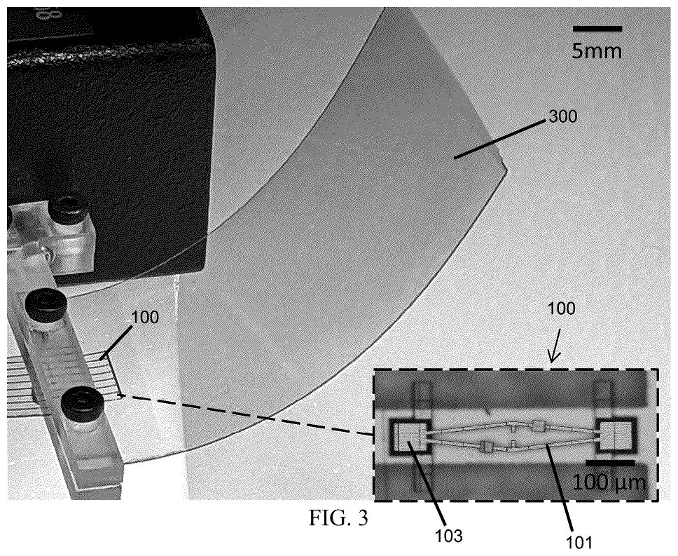

In another example fabrication embodiment, the first step in this fabrication process starts with a 175 μm thick Indium/Tin oxide (ITO)-coated PET (polyethylene terephthalate) (Sigma-Aldrich) wing as the substrate 102. The PET serves as the flexible wing 300 and is similar to previous wings used for flapping flight. The use of other materials can occur in other embodiments. The PET substrate 102 is cut and patterned using an LPKF U4 UV laser. In this example, 25 mm×50 mm rectangular wings 300 are cut to match previous computational work focused on strain sensing in hawkmoth wings. Holes can be cut to mount the wing to fixtures or vehicles, as shown in FIG. 3. Three fiducials are laser patterned on the top (non-ITO) side of the substrate 102. The fiducials are used as alignment markers during various stages of the fabrication process. Again, in other embodiments, comparable process steps and tools can be used, as well as variations in operating parameters.

Next, the substrate 102 is cleaned using acetone and isopropyl alcohol. A drop of IP-S 2PP resin (Nanoscribe) is placed on a 100 mm diameter 500 μm thick Borofloat 33 glass wafer (University Wafer). The substrate 102 (i.e. wing 300) is placed ITO side down directly on the IP-S. Capillary forces of the IP-S pull the PET substrate 102 flat for printing. The ITO/IP-S interface provides a contrast of refractive indexes and ensures a strong interface for the Nanoscribe device to find. The edges of the substrate 102 are secured to the glass wafer using polyimide tape as an adhesion layer 210 to prevent shifting during printing. Another drop of IP-S is placed on top of the substrate 102 to print the sensor structures 103. In other embodiments, comparable process steps, tools and operating parameter ranges can be used.

In this embodiment, the sensor structures 103 are printed using the Dip-In Laser Lithography (DiLL) process with a 25× objective. The ITO/IP-S interface that the Nanoscribe device finds is on the bottom of the substrate 102. Thus, a z-offset must be added to the structures 103 so they print on the top of the PET substrate 102. The z-offset is dependent on the film thickness and the refractive index at the interface. The z-offset can be easily found by printing alignment crosshairs until they no longer adhere to the PET surface and float away. The z-offset used with this substrate 102 is 182 μm. To ensure proper print quality in between print movements, the settling time of the piezo stage used to adjust to this z-offset was increased to 50 ms. This ensures printing does not start before the piezo is settled. Additionally, the stage velocity was reduced to 50 μms⁻¹ to reduce viscous flow in the resin that can arise from fast stage movements. In other embodiments, comparable process steps, tools and operating parameter ranges can be used.

Next, a coordinate transformation is completed by using marker alignment to the laser patterned fiducials. The structures are printed, and the PET substrate 102 is removed from the glass wafer and developed in PGMEA for 20 min. After development, the wing 300 is rinsed with isopropyl alcohol and dried with a nitrogen spray gun. To make the substrate 102 and 3D structures 103 electrically conductive, gold or other suitable conductive materials are sputtered to a thickness of 75 nm using a Perkin Elmer 6J Sputtering System. Other sputtering systems and thin film deposition processes also can be used. For example, chemical vapor deposition, laser metal deposition, physical vapor deposition, thin film deposition, electroless plating, and other processes known in the art can be used.

Electrical isolation can be achieved using several different methods. Overhangs 106 are printed directly on the 3D structures 103 that add local electrical isolation, as shown in FIG. 4. Sputtering gold or other suitable metals is predominantly a line-of-sight deposition process; during sputtering, the overhangs provide a self-mask that gives local electrical isolation to the sensors (see FIG. 4). After sputtering, the sensor 100 is placed in the LPKF laser cutter and aligned to the fiducials. The gold is removed from the PET substrate 102 with a laser power of 0.4 W. This ablation process is used to pattern the larger electrical traces and create global isolation separating the sensors 100 for signal acquisition. In other embodiments, comparable process steps, tools and operating parameter ranges can be used.

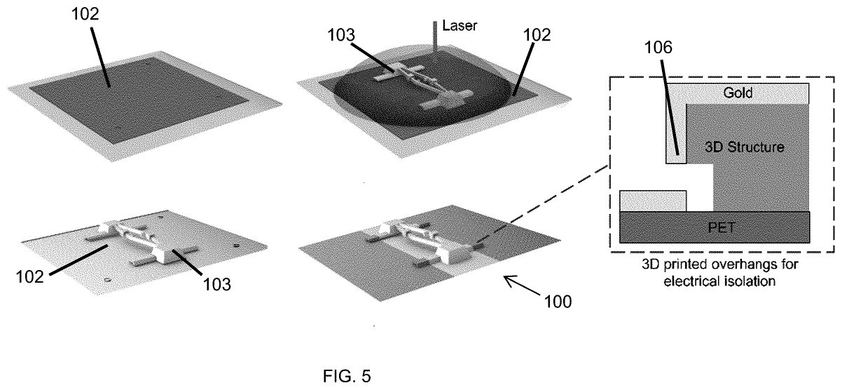

FIG. 5 is a diagram of the fabrication process, according to this embodiment. First, the PET substrate 102 is laser cut and adhered to a glass wafer (top left). Next, the sensor structures 103 are printed in IP-S photoresist directly on the PET substrate 102 using two-photon polymerization (top right). Then, gold is sputtered to add electrical conductivity to the sensor structures 103 and wing substrate 102 (bottom left). Finally, a UV laser is used to pattern the gold providing electrical isolation between the sensor structures 103. The call-out illustration shows a cross-section of 3D printed overhangs 106 that are used for electrical isolation during the deposition of gold. This rapid fabrication process allows for quick design iteration in addition to a robust sensor that has demonstrated a cycle life of greater than 50,000 cycles at 25 Hz.

### Bio-Inspired Strain Switch

This fabrication process, as detailed above, can be used to fabricate bio-inspired strain sensor 100 capable of sensing strain across a flexible wing 300 or similar structure subject to cyclical loading. The sensor's design uses chevron-shaped beams 101 to mechanically amplify displacements due to strain. The amplified displacements close a contact switch 111 when a specific strain threshold is reached. Unlike a traditional analog strain sensor that can provide continuous strain measurements, this sensor design results in a digital indication of strain passing a given threshold.

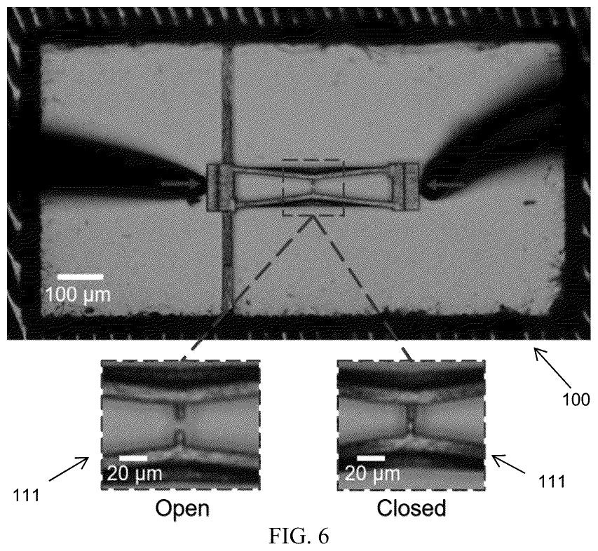

The sensors' beams 101 can be configured to detect tensile strain (see FIG. 1) or compressive strain (see FIG. 6). As shown in FIG. 6, the switch 111 of the sensor 100 is activated using probes by supplying a compressive force (i.e. direction of arrows). The call-outs highlight the contact area of the switch 111. During printing, the pads 110 of the sensor 100 are isolated from one another using overhanging structures 106 that act as self-shadowing objects during metal deposition. These overhangs 106 provide local electrical isolation on the sensors 100. Laser ablation can then be used to globally isolate the structures 101/103 from one another. In one embodiment, a contact resistance of 37Q was measured by inducing a compressive strain using probes, causing the switch 111 to close. Other measures of resistance also can be used.

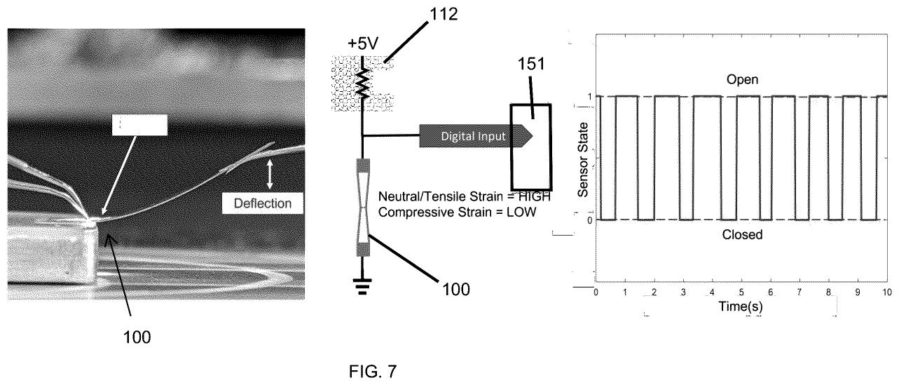

In one embodiment, the sensor 100 can be used to detect bending strain in the substrate 102 by connecting probes directly to an Arduino Uno microcontroller 151. The sensor 100 was placed in a cantilever configuration with the sensors at the base of the PET cantilever (FIG. 7). A probe was used to deflect the end of the cantilever, causing a compressive strain on the top of the substrate 102. One side of the sensor 100 was connected to a ground pin and the other to a digital pin on the microcontroller. An internal pull-up resistor (20 kΩ) completes the voltage divider circuit 150 (see FIG. 7). While a microcontroller 151 is described in this example as hardware, the microcontroller 151 may comprise controller, a microcomputer, a microprocessor, an application specific integrated circuit, a programmable logic array, a logic device, an arithmetic logic unit, a digital signal processor, or another data processor and supporting electronic hardware and software.

The switch 111 of the sensor 100 is normally open when the substrate 102 is flat, registering 5V on the digital pin. The end of the substrate 102 was deflected up, resulting in a compressive bending strain that closes the switch 100 dropping the voltage to 0V. The digital signal generated from the sensor 100 and measured on the microcontroller 151 is shown in FIG. 7. FIG. 7 shows a sensor 100 undergoing bending strain by deflecting the end of the substrate 102, where the other end of the substrate 102 is mounted to a stationary object. The sensor 100 replaces a switch in a voltage divider and the signals can be captured by a digital pin on a microcontroller. Output of the digital signal from the microcontroller 151 is obtained by opening and closing the strain switch 111 of the sensor 100 with bending strain.

Sampling the signal directly with the digital pin on the microcontroller 151 demonstrates the ability to gain important data such as strain thresholds with precise timing and extremely low latency as compared to more traditional methods of measuring strain on wings. In addition, no additional amplifiers or other circuitry is required. In contrast, traditional analog sensors commonly require an analog-to-digital converter, an amplifier, and a filter. For the present sensor 100, none of this hardware is required. Similar to the biological campaniform sensilla sensors, the sensor's mechanical structure is designed to operate as a filter without requiring additional hardware because the sensor 100 acts as a filter by taking continuous strain data and discretizing it into digital data. Stated differently, the ‘on/off’ nature of the sensor 100 is analogous to what is happening in biological systems and thus is acting as a mechanical filter. In other embodiments, comparable process steps, tools and operating parameter ranges can be used.

In one embodiment, the sensor 100 was designed to detect and output a binary response to a strain threshold being crossed in a flapping wing 300. This required developing a sensor 100 that could be incorporated into the wing 300 and withstand strains throughout the flapping cycle when, in one nonlimiting example, the wing is flapped at 25 Hz. In addition, the sensor 100 in this application should be sensitive enough to detect the relatively small strains experienced in the thin, flexible wings 300 and should not affect the stiffness and overall performance of the wing 300.

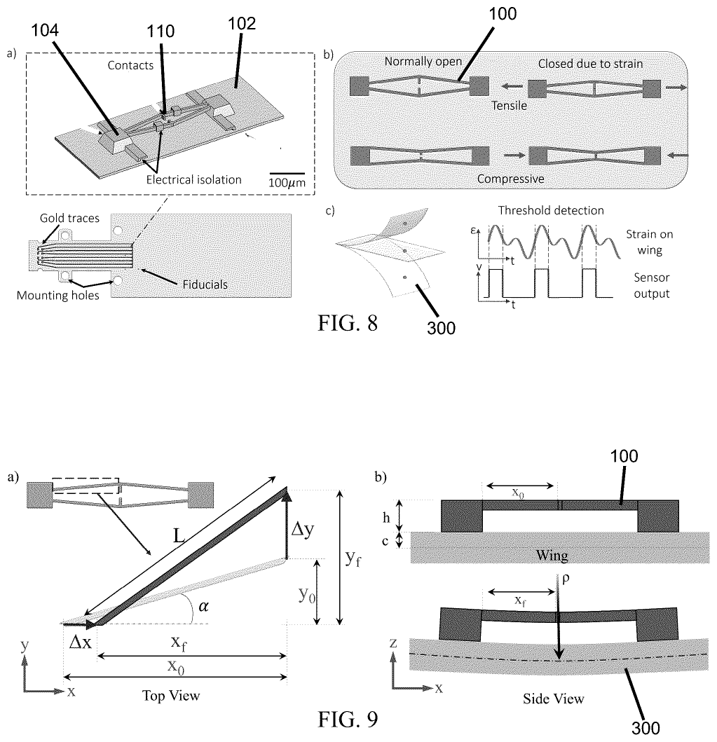

By way of further example, in the embodiment shown in FIG. 8, the sensor 100 is comprised of two chevron-shaped fixed-end beams 101 that provide a mechanical gain with respect to displacement. This mechanical amplification is needed to turn small strains in the wing 300 into a detectable displacement. The chevron beams 101 are lifted off of the substrate 102 with risers 104 to allow motion unconstrained by the substrate 102. The risers 104 can also provide an additional mechanical gain on bent surfaces by extending the distance from the neutral axis of the bent wing 300. When the substrate 102 undergoes a longitudinal strain, the beams 101 amplify this displacement causing the contacts 110 centered on each chevron-shaped beam 101 to touch once a given displacement has been reached. The beams 101 can be configured to detect a strain threshold due to either tensile or compressive strain in the substrate, as shown in FIG. 8 (top right).

The flapping motion of the wing 300 causes large strains in the substrate 102 that are cyclical based on the flapping frequency. The sensors 100 can be designed to open and close around a specific strain threshold. The sensor 100 is coupled with a pull-down resistor 112 to output a square wave (rising edge when closed, falling edge when open). One benefit of using a contact-based sensor 100 over traditional analog sensors is the signal-to-noise ratio. Traditional strain sensing approaches capture an analog signal using a Wheatstone bridge circuit and amplify it along with noise in the system. The noise must be filtered to obtain a usable signal. This amplification and signal processing takes up space, time, computational power, and electric power. The digital strain sensor 100, on the other hand, has a binary output and the signal can be measured directly using the digital pin on a microcontroller 151 where the sampling rate is not limited by an analog-to-digital converter (ADC) but instead by the clocking speed of the processor of the microcontroller 151. This unique approach to measuring dynamic strain in a substrate 102 creates a type of mechanical filtering in response to the flapping strain as shown in FIG. 8 (bottom).

FIG. 9 is a schematic of the kinematic relationship between the design parameters, including the length of the beams 101 and its deflection under strain (i.e. displacement in the longitudinal (x) axis to the transverse (y) axis), where the strain measured in a substrate 102 in terms of the sensor's parameters are:

$${ε}_{substrate} = [ 1 - \frac{\sqrt{{( {x}_{0} / cos α )}^{2} - {( {y}_{0} - Δ y )}^{2}}}{{x}_{0}} ] ( \frac{c + h}{c} )$$

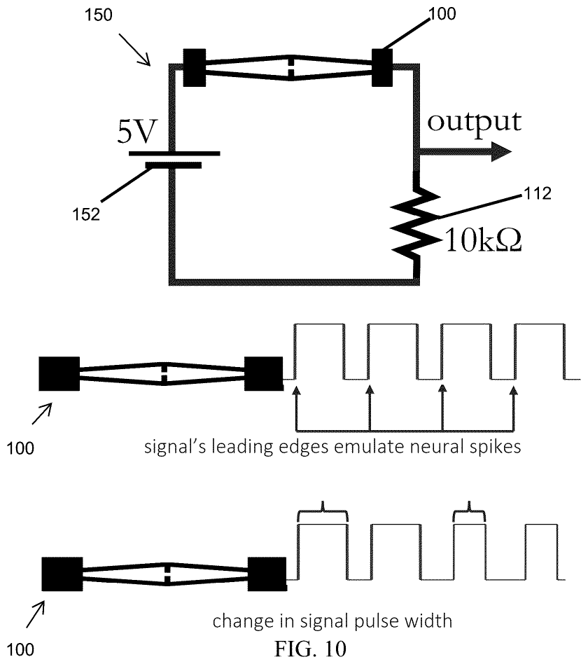

To generate a signal, in one embodiment shown in FIG. 10, the sensors 100 were coupled with a 10 kΩ pull-down resistor 112 to output a square wave during wing flapping. FIG. 10 shows a circuit diagram and sensor 100 outputs. The sensor 100 acts as a switch 111 and is incorporated into a voltage divider 150 to generate a digital signal. The timing of the leading edge of a single sensor's square wave is similar to neural spikes from biological mechanosensors. The pulse width of the ‘on’-time of the sensor 100 during each flap cycle can also provide a measure of disturbances on the wing 300. A power supply 152 provides 5V to the circuit. When the switch 111 of the sensor 100 is open, the output is low; when a strain threshold has been reached and the switch 111 closes, the signal changes to a high state. In other embodiments, the parameters of the resistor and power can vary.

In one embodiment, a quasistatic test of one sensor 100 was carried out to validate a model of the strain and ensure the strain threshold was within the maximum strain during flapping. A cantilever deflection test was done to calculate the strain in the substrate 102 at the sensor's location. The sensor 100 was printed 2 mm from the base of the wing 300. A displacement was then applied at a distance L₂=6 mm from the base of the wing 300 to bend the wing until a change in the digital signal was observed, indicating that the switch 111 was closed and the strain threshold had been reached. Photos were taken of the wing before and after the displacement to photogrammetrically calculate the total applied displacement, δ. Using a linear elastic model, the distance from the point of displacement to the sensor 100 and the thickness of the substrate 102 are considered.

Next, three sensors 100 with different designed thresholds were used to test the general response of the sensor 100 on a flapping wing 300 and demonstrate how the signal timing can be affected through sensor design. The three sensors 100 were centered along the chord and placed 2 mm from the base of the wing 300. The sensors 100 were connected to the digital pins on an Arduino UNO microcontroller 151, and the wing 300 was flapped at a frequency of (5 Hz). These parameters can vary in other embodiments.

The third experiment was designed to demonstrate the effect of wind disturbances on the sensors' activation timing. A PET wing 300 was designed with a sensor 100 centered along the chord of the wing 300. This wing 300 was then attached to the shaft of an Aurora Scientific Model 300C-LR Dual-Mode Lever Arm system. The flapping motion of a hawkmoth's wing can be modeled as the sum of two sine waves. A signal was generated with a primary frequency of 25 Hz with a 15° flapping amplitude (A₁) and a secondary frequency of 50 Hz with 20% of the primary amplitude, A₂.

$$Signal = {A}_{1} * sin ( 2 π * 25 t ) + {A}_{2} * sin ( 2 π * 50 t ) \qquad ( 9 )$$

Wind disturbance can be tested using an experimental setup. A hair dryer was used to generate a wind gust of 3 m/s to provide a disturbance to the flapping wing. A 25 Hz+50 Hz flapping signal activated the motor. The signal was generated in MATLAB and output to the Lever Arm's length driver via a National Instruments X-Series DAQ (see FIG. 10). To sample the sensor's signal, a spring-loaded connector was used to make contact with the conductive traces. The signal was read with the digital input on the NI DAQ at a sampling rate of 1 MHz.

Sensor data was collected from one sensor 100 during flapping only as well as flapping plus a wind disturbance. Two methods were used to evaluate timing differences when a disturbance was added. In the first, the timing of the rising edge was noted as may be captured using a microcontroller interrupt function (see FIG. 10, middle). This approach is also similar to the spiking in the campaniform sensilla. The second approach simply measured the pulse width of the ‘on’-time of the sensor 100 to look for changes that might indicate a disturbance (see FIG. 10, bottom).

Quasistatic test and Model Comparison: After gold is deposited during the fabrication process, residual stresses remain in the substrate and the sensors 100. This residual stress adds an unwanted pre-strain to the wing and the sensors 100. As a result, the dimensions of the fabricated sensor 100 can be significantly different from the design. Instead of using the designed parameters of the sensor 100 in this test to confirm the accuracy of the analytical model, the sensor's fabricated dimensions were obtained using a confocal microscope (Zeiss LSM400). These dimensions were used in the analytical model and gave a theoretical strain threshold of 3.25 millistrain. The results from the quasistatic test indicated an activation at 3.4 millistrain. These numbers show agreement between the model and the experimental results and provide a general guideline for sensor design. It's important to note that there is no mapping between the sensor and strain threshold, but instead the focus is when changes are happening through the modulation of pulses generated by the sensor.

Three Sensor Threshold: The timing of the output of the sensor 100 can be varied using different sensor designs to target different strain thresholds. Three sensors 100 were designed with theoretical strain thresholds of 3000, 3500, and 4000 microstrain, although as indicated in the quasistatic results, the fabricated strain thresholds can differ significantly from the designs. Further, the sensor 100 can be designed with different strain thresholds by varying varying the geometric parameters of the sensor 100. For example, the strain threshold can be achieved by varying the length of the beams 101, the angle between the beams 101, the gap between the beams 101, and the height of the sensor 100 and its components 101/102. A longer sensor 100 for instance is more sensitive to strain and thus activates at a lower strain threshold. A lower angle or a smaller gap also increases the sensitivity. A taller sensor 100 would also be more sensitive. These parameters can be changed individually or together to achieve a desired strain threshold.

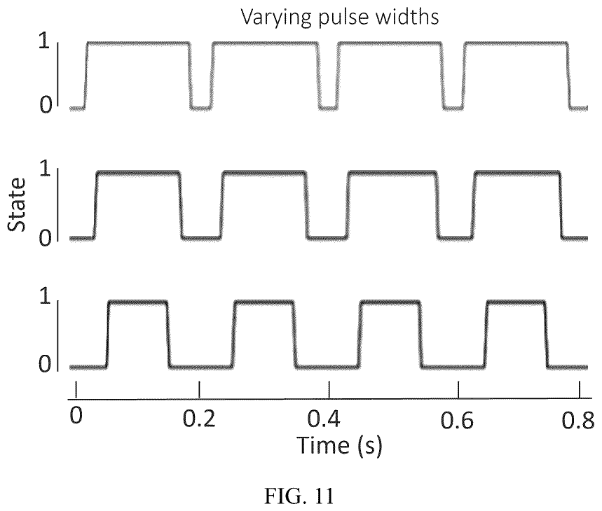

The sensors 100 were tested on a wing with a flapping frequency of 5 Hz. FIG. 11 shows the effect of changing the target threshold to achieve pulse width modulation of the sensor output. Even though the strain thresholds in the fabricated sensors 100 differed from the designs, the trends remained. In FIG. 11, the changing pulse widths indicate that the threshold strain is sensed at different points within the flap cycle.

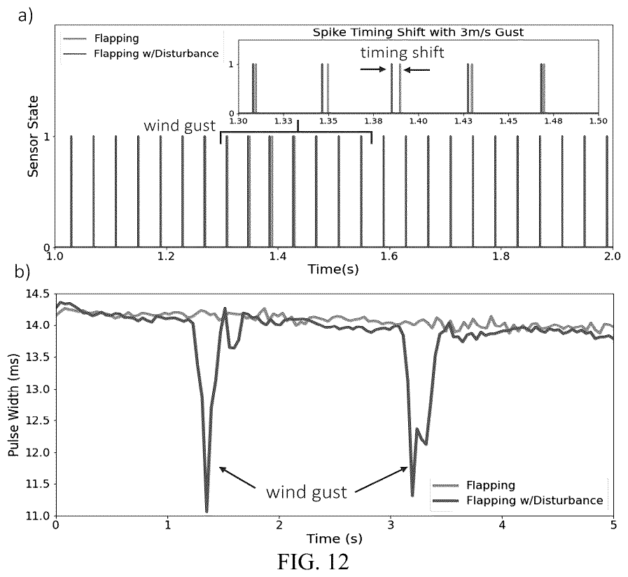

Detecting disturbances with rising edge: In one embodiment, a single sensor 100 was tested with flapping only and flapping with a 3 m/s wind disturbance. The timing of the rising edge of the square wave was measured and plotted to emulate the action potentials of the hawkmoth (see FIG. 12, top) When the wind gust is introduced, the flapping cycle of the wing is changed, which affects the timing of the sensor responses and can be seen as a shift from the expected timing of the sensor activation. As shown in FIG. 12, the wind gusts cause slight changes in the activation timing of the sensor 100. The gust is detected by analyzing the pulse width timing from the strain threshold sensor 100. The wind gust causes a noticeable change in this pulse width timing.

While a sensor 100 used with a flexible wing 300 is discussed in the above example, the sensor 100 can be used to detect any strain-related event in which a threshold is exceeded by identifying the rising edge. For example, if a beam or plate bends beyond a particular threshold, the sensor 100 could indicate the event. In this example, the sensor 100 could be incorporated into a package and indicate tampering if the tampering causes the strain to exceed the threshold.

Detecting disturbances with pulse width: Next, the pulse width of the sensor's digital output was plotted. In this case, the pulse width represented approximately one third of a total wingbeat period at approximately 14 ms when no disturbance was applied. The applied wind disturbance is shown as a clear deviation from the nominal pulse width in FIG. 12 (bottom).

When used in this specification and claims, the terms “comprises” and “comprising” and variations thereof mean that the specified features, steps, or integers are included. The terms are not to be interpreted to exclude the presence of other features, steps or components.

The invention may also broadly consist in the parts, elements, steps, examples and/or features referred to or indicated in the specification individually or collectively in any and all combinations of two or more said parts, elements, steps, examples and/or features. In particular, one or more features in any of the embodiments described herein may be combined with one or more features from any other embodiment(s) described herein.

Protection may be sought for any features disclosed in any one or more published documents referenced herein in combination with the present disclosure. Although certain example embodiments of the invention have been described, the scope of the appended claims is not intended to be limited solely to these embodiments. The claims are to be construed literally, purposively, and/or to encompass equivalents.

What is claimed is:

1. A strain sensor comprising:
a flexible substrate;
a pair of beams disposed on the flexible substrate, wherein the pair of beams are electrically conductive; and
a contact pad disposed on each beam of the pair of beams, forming a switch.

2. The strain sensor of claim 1, wherein the contact pad on each beam of the pair of beams are in electrical contact when the flexible substrate experiences a strain beyond a threshold.

3. The strain sensor of claim 2, wherein the pair of beams amplify the strain experienced by the substrate.

4. The strain sensor of claim 1, further comprising:
a riser separating each beam of the pair of beams from the flexible substrate.

5. The strain sensor of claim 1, wherein the contact pad comprises a conductive material selected from a group consisting of aluminum, gold, platinum, palladium, silver, and alloys of gold, platinum, palladium, or silver.

6. The strain sensor of claim 1, further comprising:
a voltage divider circuit in electrical communication with the contact pad.

7. The strain sensor of claim 1, further comprising a microcontroller adapted to read a signal from the contact pad.

8. The strain sensor of claim 7, wherein the microcontroller receives a digital signal corresponding to an open or closed position of the switch.

9. The strain sensor of claim 8, wherein the microcontroller receives the digital signal without an amplifier, an analog-to-digital converter, or a filter.

10. The strain sensor of claim 1, wherein each beam of the pair of beams is chevron-shaped.

11. The strain sensor of claim 1, wherein several sensors are arranged into an array.

12. The strain sensor of claim 1, wherein the sensor is incorporated into a flexible wing.

13. The strain sensor of claim 1, wherein the switch is adapted to transition from an open position to a closed position in response to a strain imparted on the flexible substrate.

14. The strain sensor of claim 12, wherein the switch is in the closed position when the strain exceeds a threshold.

15. A method of fabricating a sensor, comprising:
providing a flexible substrate;
forming sensor structures on the flexible substrate using an additive manufacturing process;
applying a layer of conductive material over the flexible substrate and sensor structures; and
ablating a portion of the flexible substrate and/or sensor structures to electrically isolate the sensor structures.

16. The method of claim 15, wherein ablating comprises laser ablation.

17. The method of claim 15, further comprising:
mounting the flexible substrate to a carrier using an adhesion layer.

18. The method of claim 15, wherein the sensor structures comprise chevron-shaped beams.

19. The method of claim 15, further comprising:
forming overhanging structures, wherein the overhanging structures shadow at least one of the flexible substrate and the sensor structures when applying the layer of conductive material.

20. The method of claim 15, applying the conductive material comprises sputtering.

21. A method of using a sensor, the sensor providing a digital signal in response to a strain experienced by the sensor, the method comprising:
attaching the sensor to an object, wherein the sensor comprises a switch-based device having state existing as off or on;
identifying a change in the state of the switch-based device.

22. The method of claim 21, further comprising:
acquiring the digital signal over a period of time when the object experiences a cyclical movement;
measuring a pattern in the digital signal created by the cyclical movement; and
identifying a deviation in the pattern.

23. The method of claim 22, wherein the digital signal comprises a square wave and the pattern repeats at regular intervals.

24. The method of claim 23, wherein the disturbance comprises a shift in a timing of the intervals.

25. The method of claim 23, wherein the disturbance comprises a change in a pulse width of the square wave.

26. The method of claim 21, wherein the change is a leading edge of a square wave.
